(19) United States
(12) Patent Application Publication
(10) Pub. No.: US 2012/0242923 A1
(43) Pub. Date: Sep. 27, 2012

(54) THIN FILM TRANSISTOR SUBSTRATE, METHOD FOR MANUFACTURING THE SAME, AND DISPLAY DEVICE

(75) Inventors: Tadayoshi Miyamoto, Osaka-shi (JP); Kazuhide Tomiyasu, Osaka-shi (JP)

(73) Assignee: Sharp Kabushiki Kaisha, Osaka-shi, Osaka (JP)

(21) Appl. No.: 13/513,695

(22) PCT Filed: Oct. 28, 2010
(86) PCT No.: PCT/JP2010/006369

§ 371 Date: Jun. 4, 2012

(30) Foreign Application Priority Data
Feb. 25, 2010 (JP) 2010-040208

(51) Int. Cl. H01L 33/08; G02F 1/136

(52) U.S. Cl. 349/43; 257/43; 438/34; 257/E33.053

(57) ABSTRACT

An active matrix substrate (20a) includes a gate electrode (11aa), a gate insulating layer (12) covering the gate electrode (11aa), an oxide semiconductor layer (13a) provided on the gate insulating layer (12) and having a channel region (C), a source electrode (16aa) and a drain electrode (16b) provided on the oxide semiconductor layer (13a), an interlayer insulating film (17) covering the oxide semiconductor layer (13a), the source electrode (16aa), and the drain electrode (16b), and a planarization film (18) provided on the interlayer insulating film (17). An opening (Ca) reaching the interlayer insulating film (17) is formed at a portion of the planarization film (18) which is located over the channel region (C).

### TECHNICAL FIELD

The present invention relates to thin film transistors, and more particularly, to thin film transistor substrates including a semiconductor layer made of an oxide semiconductor, methods for manufacturing the same, and display devices.

### BACKGROUND ART

An active matrix substrate includes thin film transistors (hereinafter also referred to as “TFTs”) as switching elements, one for each pixel, which is the smallest unit of an image.

In recent years, for active matrix substrates, a TFT including a semiconductor layer made of an oxide semiconductor (hereinafter also referred to as an “oxide semiconductor layer”) has been proposed as a switching element for each pixel, which is the smallest unit of an image, instead of conventional thin film transistors including a semiconductor layer made of amorphous silicon.

For example, a typical bottom-gate TFT includes a gate electrode provided on an insulating substrate, a gate insulating layer covering the gate electrode, an island-like semiconductor layer provided on the gate insulating layer over the gate electrode, and a source electrode and a drain electrode provided on the semiconductor layer, facing each other.

In the bottom-gate TFT, an upper portion of the channel region is covered by an interlayer insulating film made of SiO₂ etc., and a surface of the interlayer insulating film is covered by a planarization film made of acrylic resin etc. (see, for example, Patent Document 1).

A pixel electrode is formed on the planarization film. Thus, an active matrix substrate is manufactured. A counter substrate is provided to face the active matrix substrate. A liquid crystal layer is provided between the active matrix substrate and the counter substrate. As a result, a liquid crystal display device is manufactured.

### CITATION LIST

### Patent Document

PATENT DOCUMENT 1: Japanese Patent Publication No. H08-279615

### SUMMARY OF THE INVENTION

### Technical Problem

Here, in a display device employing the bottom-gate TFT, water molecules or ions (positive ions) in the liquid crystal layer (electro-optic material) are attracted by the potential of the gate electrode etc., and get stuck as positive charge at an interface between the planarization film and the liquid crystal layer on the planarization film. These water molecules or ions diffuse downward in the planarization film, resulting in charge (positive charge) at an interface between the interlayer insulating film and the planarization film.

This charge forms a back channel in the channel region of the TFT, leading to variations in the threshold voltage of the TFT and a leakage current. As a result, the characteristics of the TFT are disadvantageously degraded.

The present invention has been made in view of the above problem. It is an object of the present invention to provide a thin film transistor substrate which is used in a TFT having a bottom gate structure and in which variations in threshold voltage and a leakage current are reduced, whereby the degradation in characteristics of the TFT is effectively reduced, and a method for manufacturing the thin film transistor, and a display device.

### Solution to the Problem

To achieve the object, a thin film transistor substrate according to the present invention includes an insulating substrate, a gate electrode provided on the insulating substrate, a gate insulating layer covering the gate electrode, a semiconductor layer provided on the gate insulating layer over the gate electrode and having a channel region, a source electrode and a drain electrode provided on the semiconductor layer, overlapping the gate electrode and facing each other with the channel region being interposed between the source electrode and the drain electrode, an interlayer insulating film covering the semiconductor layer, the source electrode, and the drain electrode, a planarization film provided on the interlayer insulating film, and a pixel electrode provided on the planarization film. An opening reaching the interlayer insulating film is formed at a portion of the planarization film which is located over the channel region.

With the configuration, for example, in a liquid crystal display device including a bottom-gate thin film transistor, even if water molecules or ions (positive ions) in the liquid crystal layer are attracted by the potential of the gate electrode etc., and get stuck as positive charge at an interface between the planarization film and the liquid crystal layer on the planarization film, the downward diffusion of these water molecules or ions in the planarization film over the channel region of the semiconductor layer can be reduced or prevented. Also, the occurrence of charge (positive charge) at an interface between the interlayer insulating film and the planarization film can be reduced or prevented. Therefore, the formation of a back channel in the channel region of the semiconductor layer due to the charge can be reduced or prevented. As a result, variations in threshold voltage and the occurrence of a leakage current of the thin film transistor can be reduced, whereby a degradation in characteristics of the thin film transistor can be effectively reduced.

Because variations in threshold voltage and the occurrence of a leakage current of the thin film transistor can be reduced, whereby a degradation in characteristics of the thin film transistor can be effectively reduced, and therefore, a thin film transistor substrate including not only a thin film transistor having a leakage current low enough to allow the thin film transistor to be used in a pixel switching element, but also a thin film transistor having a threshold voltage low enough to allow the thin film transistor to be used in a peripheral circuit and which can be driven at high speed, can be provided, for example.

In the thin film transistor substrate of the present invention, the pixel electrode may be provided on a surface of the opening.

With the configuration, the channel region of the semiconductor layer is covered by the pixel electrode, whereby the formation of a back channel in the channel region of the semiconductor layer due to charge can be reliably reduced or prevented, and therefore, variations in threshold voltage and the occurrence of a leakage current of the thin film transistor can be reliably reduced.

In the thin film transistor substrate of the present invention, a channel protection layer may be provided on the channel region of the semiconductor layer to protect the channel region.

With the configuration, when patterning is performed by etching to form the source electrode and the drain electrode in a step of forming the source electrode and the drain electrode, the channel region of the semiconductor layer can be protected from etching.

In the thin film transistor substrate of the present invention, the semiconductor layer may be an oxide semiconductor layer.

With the configuration, compared to a thin film transistor employing amorphous silicon in the semiconductor layer, the above thin film transistor has a higher electron mobility and can be formed by a lower-temperature process.

In the thin film transistor substrate of the present invention, the oxide semiconductor layer may be made of metal oxide containing at least one selected from the group consisting of indium (In), gallium (Ga), aluminum (Al), copper (Cu), and zinc (Zn).

With the configuration, the oxide semiconductor layer made of these materials can have a high mobility even if the oxide semiconductor layer is in the amorphous state, and therefore, can provide a large on resistance of a switching element.

In the thin film transistor substrate of the present invention, the oxide semiconductor layer may be made of In—Ga—Zn—O metal oxide.

With the configuration, the thin film transistor can have satisfactory properties, i.e., a high mobility and a low off current.

In the thin film transistor substrate of the present invention, the semiconductor layer may be a silicon-based semiconductor layer.

The thin film transistor substrate of the present invention also has excellent properties that variations in threshold voltage and the occurrence of a leakage current of the thin film transistor can be reduced, whereby a degradation in characteristics of the thin film transistor can be effectively reduced. Therefore, the present invention can be preferably applicable to a display device including the thin film transistor substrate, a counter substrate facing the thin film transistor substrate, and a display medium layer provided between the thin film transistor substrate and the counter substrate. The present invention is also preferably applicable to a display device including a liquid crystal layer as the display medium layer.

A thin film transistor substrate manufacturing method according to the present invention is a method for manufacturing a thin film transistor substrate including an insulating substrate, a gate electrode provided on the insulating substrate, a gate insulating layer covering the gate electrode, a semiconductor layer provided on the gate insulating layer over the gate electrode and having a channel region, a source electrode and a drain electrode provided on the semiconductor layer, overlapping the gate electrode and facing each other with the channel region being interposed between the source electrode and the drain electrode, an interlayer insulating film covering the semiconductor layer, the source electrode, and the drain electrode, a planarization film provided on the interlayer insulating film, and a pixel electrode provided on the planarization film. The method includes at least a gate electrode forming step of forming the gate electrode on the insulating substrate, a semiconductor layer forming step of forming the gate insulating layer covering the gate electrode formed in the gate electrode forming step, and thereafter, forming the semiconductor layer on the gate insulating layer, a source/drain forming step of forming the source electrode and the drain electrode on the oxide semiconductor layer formed in the semiconductor layer forming step, and exposing the channel region of the oxide semiconductor layer, an interlayer insulating film forming step of forming the interlayer insulating film covering the semiconductor layer, the source electrode, and the drain electrode, a planarization film forming step of forming the planarization film on a surface of the interlayer insulating film, and an opening forming step of forming an opening reaching the interlayer insulating film at a portion of the planarization film which is located over the channel region.

With the configuration, for example, in a liquid crystal display device including a bottom-gate thin film transistor, even if water molecules or ions (positive ions) in the liquid crystal layer are attracted by the potential of the gate electrode etc., and get stuck as positive charge at an interface between the planarization film and the liquid crystal layer on the planarization film, the downward diffusion of these water molecules or ions in the planarization film over the channel region of the semiconductor layer can be reduced or prevented. Also, the occurrence of charge (positive charge) at an interface between the interlayer insulating film and the planarization film can be reduced or prevented. Therefore, the formation of a back channel in the channel region of the semiconductor layer due to the charge can be reduced or prevented. As a result, variations in threshold voltage and the occurrence of a leakage current of the thin film transistor can be reduced, whereby a degradation in characteristics of the thin film transistor can be effectively reduced. Thus, a thin film transistor substrate having these features can be provided.

Because variations in threshold voltage and the occurrence of a leakage current of the thin film transistor can be reduced, whereby a degradation in characteristics of the thin film transistor can be effectively reduced, and therefore, a thin film transistor substrate including not only a thin film transistor having a leakage current low enough to allow the thin film transistor to be used in a pixel switching element, but also a thin film transistor having a threshold voltage low enough to allow the thin film transistor to be used in a peripheral circuit and which can be driven at high speed, can be provided, for example.

### ADVANTAGES OF THE INVENTION

According to the present invention, variations in threshold voltage and the occurrence of a leakage current of a thin film transistor can be reduced, whereby a degradation in characteristics of the thin film transistor can be effectively reduced.

### BRIEF DESCRIPTION OF THE DRAWINGS

FIG. 1 is a cross-sectional view of a liquid crystal display device including an active matrix substrate including a thin film transistor according to a first embodiment of the present invention.

FIG. 2 is a plan view of the active matrix substrate including the thin film transistor of the first embodiment of the present invention.

FIG. 3 is an enlarged plan view of a pixel portion and a terminal portion of the active matrix substrate including the thin film transistor of the first embodiment of the present invention.

FIG. 4 is a cross-sectional view of the active matrix substrate taken along line A-A of FIG. 3.

FIG. 5 is a cross-sectional view for describing a process of manufacturing the thin film transistor and the active matrix substrate of the first embodiment of the present invention.

FIG. 6 is a cross-sectional view for describing a process of manufacturing a counter substrate.

FIG. 7 is a cross-sectional view of an active matrix substrate including a thin film transistor according to a second embodiment of the present invention.

FIG. 8 is a cross-sectional view for describing a process of fabricating the thin film transistor and the active matrix substrate of the second embodiment of the present invention.

FIG. 9 is a cross-sectional view showing an active matrix substrate including the thin film transistor of the present invention.

### DESCRIPTION OF EMBODIMENTS

### First Embodiment

Embodiments of the present invention will be described in detail hereinafter with reference to the drawings. Note that the present invention is not intended to be limited to the embodiments described below.

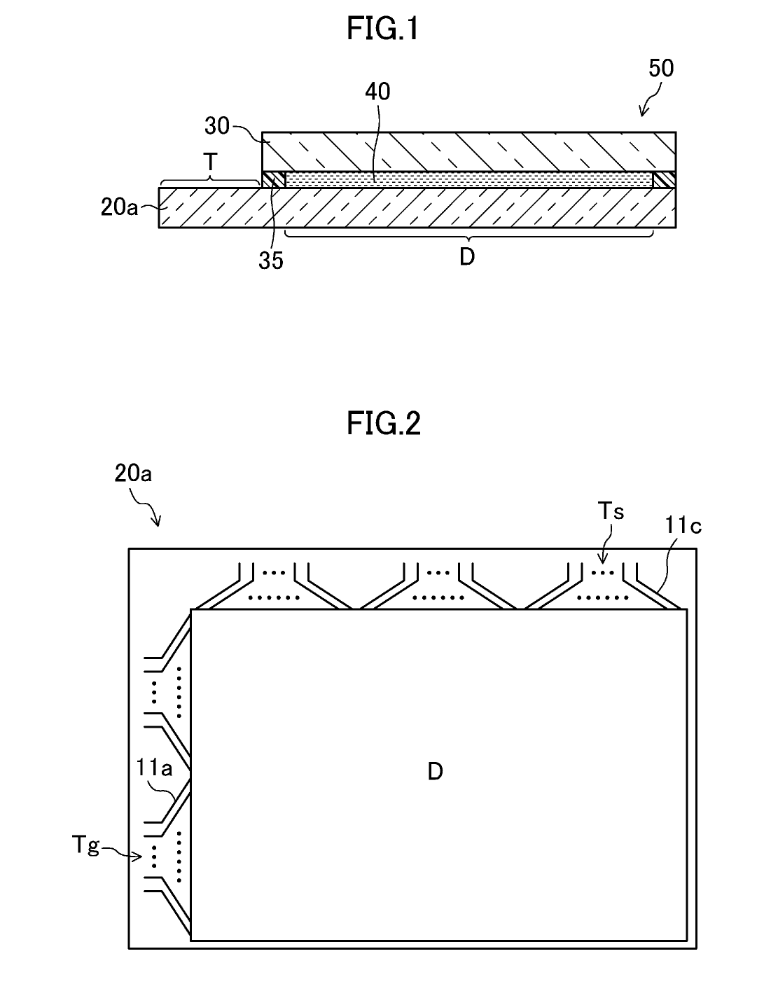

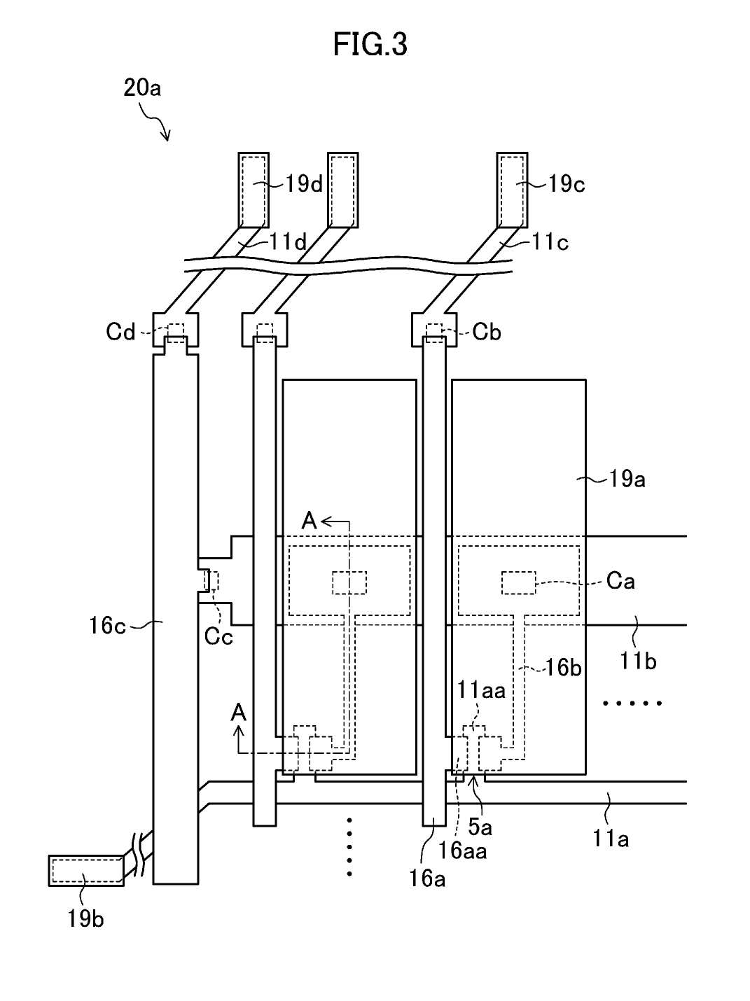

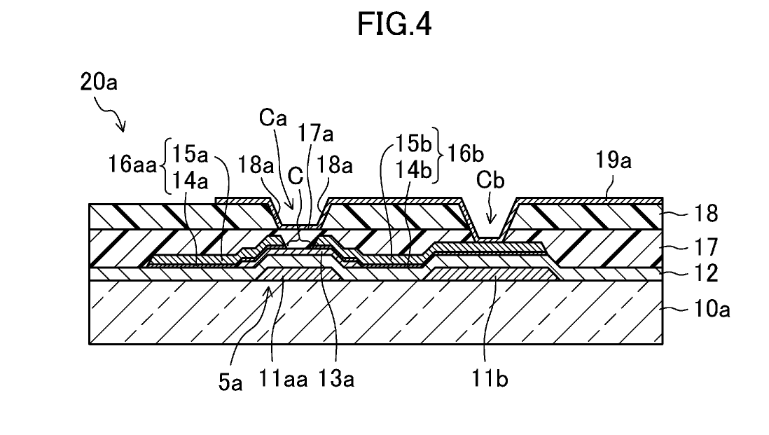

FIG. 1 is a cross-sectional view of a liquid crystal display device including an active matrix substrate including a thin film transistor according to a first embodiment of the present invention. FIG. 2 is a plan view of the active matrix substrate including the thin film transistor of the first embodiment of the present invention. FIG. 3 is an enlarged plan view of a pixel portion and a terminal portion of the active matrix substrate including the thin film transistor of the first embodiment of the present invention. FIG. 4 is a cross-sectional view of the active matrix substrate taken along line A-A of FIG. 3.

As shown in FIG. 1, the liquid crystal display device 50 includes the active matrix substrate (thin film transistor substrate) 20a and a counter substrate 30 facing each other, and a liquid crystal layer (display medium layer) 40 provided between the active matrix substrate 20a and the counter substrate 30. The liquid crystal display device 50 also includes a frame-shaped sealing member 35 which is used to join the active matrix substrate 20a and the counter substrate 30 together and enclose the liquid crystal layer 40 between the active matrix substrate 20a and the counter substrate 30.

As shown in FIG. 1, the liquid crystal display device 50 has a display region D for displaying an image in a portion inside the sealing member 35, and a terminal region T of the active matrix substrate 20a which protrudes from the counter substrate 30.

As shown in FIGS. 2, 3, and 4, the active matrix substrate 20a includes an insulating substrate 10a, a plurality of scan lines 11a provided on the insulating substrate 10a, extending in parallel to each other in the display region D, a plurality of auxiliary capacitor lines 11b each provided between the corresponding scan lines 11a, extending in parallel to each other in the display region D, and a plurality of signal lines 16a extending in a direction perpendicular to the scan lines 11a and in parallel to each other in the display region D. The active matrix substrate 20a also includes a plurality of TFTs 5a at respective corresponding interconnection portions between the scan lines 11a and the signal lines 16a (i.e., one TFT 5a is provided for each pixel), an interlayer insulating film 17 covering the TFTs 5a, a planarization film 18 covering the interlayer insulating film 17, a plurality of pixel electrodes 19a provided and arranged in a matrix on the planarization film 18 and connected to the respective corresponding TFTs 5a, and an alignment film (not shown) covering the pixel electrodes 19a.

As shown in FIGS. 2 and 3, the scan line 11a is extended into a gate terminal region Tg of the terminal region T (see FIG. 1), and is connected to a gate terminal 19b in the gate terminal region Tg.

As shown in FIG. 3, the auxiliary capacitor line 11b is connected via an auxiliary capacitor main line 16c and a relay line 11d to an auxiliary capacitor terminal 19d. Here, the auxiliary capacitor main line 16c is connected to the auxiliary capacitor line 11b via a contact hole Cc formed in a gate insulating layer 12, and to the relay line 11d via a contact hole Cd formed in the gate insulating layer 12.

As shown in FIGS. 2 and 3, the signal line 16a is extended as a relay line 11c into a source the terminal region Ts of the terminal region T (see FIG. 1), and is connected to a source terminal 19c in the source the terminal region Ts.

Here, as shown in FIG. 3, the signal line 16a is connected to the relay line 11c via a contact hole Cb formed in the gate insulating layer 12.

As shown in FIGS. 3 and 4, the TFT 5a, which has a bottom gate structure, includes a gate electrode 11aa provided on the insulating substrate 10a, the gate insulating layer 12 covering the gate electrode 11aa, and an island-like oxide semiconductor layer 13a which is provided on the gate insulating layer 12 over the gate electrode llaa and has a channel region C. The TFT 5a also includes a source electrode 16aa and a drain electrode 16b which is provided on the oxide semiconductor layer 13a, overlapping the gate electrode 11aa and facing each other with the channel region C being interposed between the source electrode 16aa and the drain electrode 16b.

Here, the interlayer insulating film 17 covering the source electrode 16aa and the drain electrode 16b (i.e., the TFT 5a) is provided on the channel region C of the oxide semiconductor layer 13a.

As shown in FIG. 3, the gate electrode 11aa is a laterally protruding portion of the scan line 11a. As shown in FIG. 3, the source electrode 16aa is a laterally protruding portion of the signal line 16a. As shown in FIG. 4, the source electrode 16aa includes a multilayer film of a first conductive layer 14a and a second conductive layer 15a.

As shown in FIGS. 3 and 4, the drain electrode 16b includes a multilayer film of a first conductive layer 14b and a second conductive layer 15b. The drain electrode 16b is connected to the pixel electrode 19a via a contact hole Ca formed in the multilayer film of the interlayer insulating film 17 and the planarization film 18. The drain electrode 16b is also provided over the auxiliary capacitor line 11b with the gate insulating layer 12 being interposed therebetwee, thereby forming an auxiliary capacitor.

The oxide semiconductor layer 13a includes, for example, an oxide semiconductor film made of indium gallium zinc oxide (IGZO) etc.

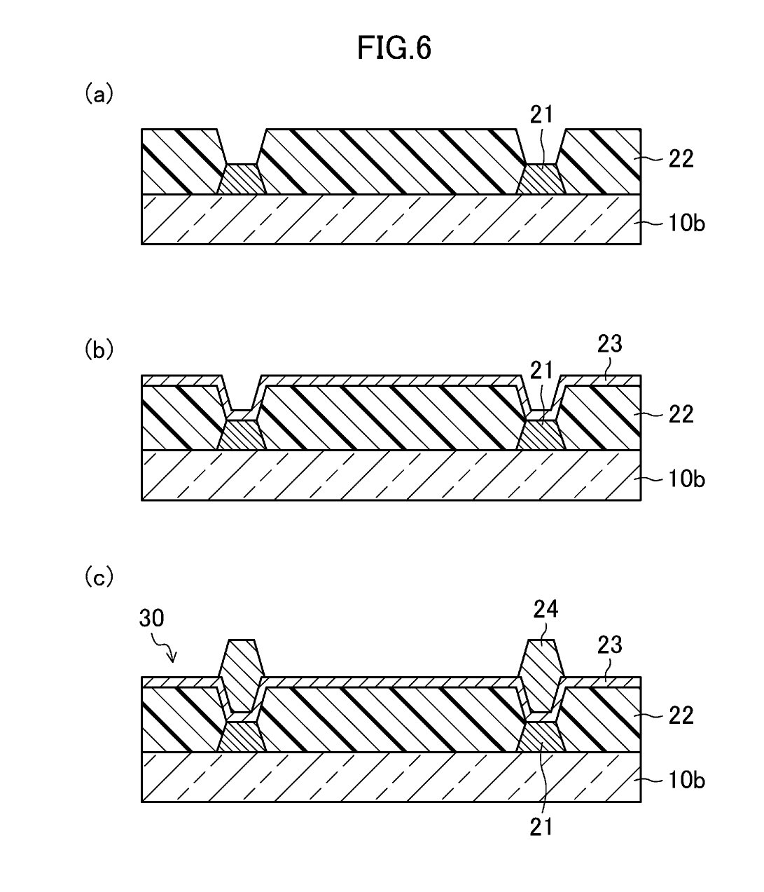

As shown in FIG. 6(c) described below, the counter substrate 30 includes an insulating substrate 10b, a black matrix 21 with a grid pattern provided on the insulating substrate 10b, and a color filter layer including color layers 22 (e.g., a red layer, a green layer, and a blue layer, etc.) which are each provided between grid bars of the black matrix 21. The counter substrate 30 also includes a common electrode 23 covering the color filter layer, a photospacer 24 provided on the common electrode 23, and an alignment film (not shown) covering the common electrode 23.

The liquid crystal layer 40 is formed of, for example, a nematic liquid crystal material having electro-optic properties.

In the liquid crystal display panel 50 thus configured, in each pixel P, when a gate signal is sent from a gate driver (not shown) through the scan line 11a to the gate electrode 11aa, so that the TFT 5a is turned on, a source signal is sent from a source driver (not shown) through the signal line 16a to the source electrode 16aa, so that predetermined charge is written through the oxide semiconductor layer 13a and the drain electrode 16b to the pixel electrode 19a.

In this case, there is a potential difference between each pixel electrode 19a of the active matrix substrate 20a and the common electrode 23 of the counter substrate 30, and therefore, a predetermined voltage is applied to the liquid crystal layer 40 (i.e., the liquid crystal capacitor of each pixel) and the auxiliary capacitor connected in parallel to the liquid crystal capacitor.

In the liquid crystal display panel 50, in each pixel P, the alignment of the liquid crystal layer 40 is changed, depending on the magnitude of the voltage applied to the liquid crystal layer 40, to adjust the light transmittance of the liquid crystal layer 40, thereby displaying an image.

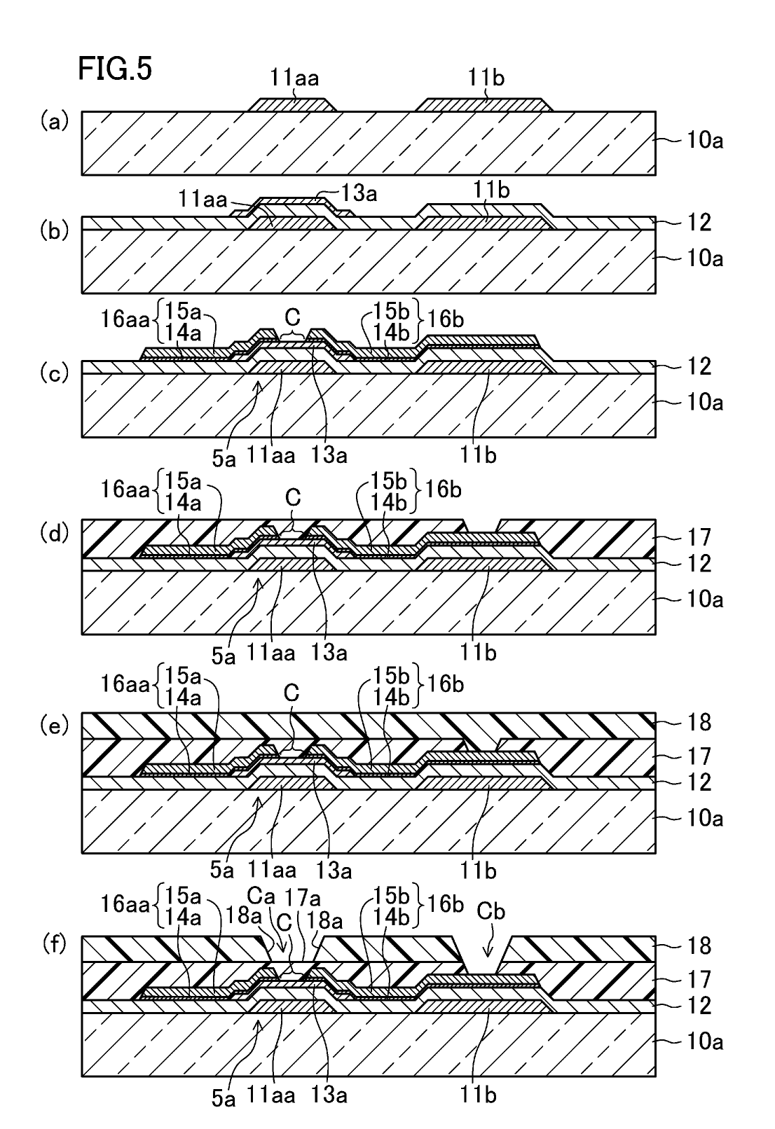

Next, an example method for manufacturing the liquid crystal display panel 50 of this embodiment will be described with reference to FIGS. 5 and 6. FIG. 5 is a cross-sectional view for describing a process of manufacturing the TFT 5a and the active matrix substrate 20a, and FIG. 6 is a cross-sectional view for describing a process of manufacturing the counter substrate 30. Note that the manufacturing method of this embodiment includes an active matrix substrate fabricating process, a counter substrate fabricating process, and a liquid crystal injecting process.

Firstly, the process of fabricating the TFT 5a and the active matrix substrate 20a will be described.

<Gate Electrode Forming Step>

Initially, for example, a molybdenum film (thickness: about 150 nm) etc. is formed by sputtering on the entire insulating substrate 10a, such as a glass substrate, a silicon substrate, a heat-resistant plastic substrate, etc. Thereafter, photolithography, wet etching, and resist removal and cleaning are performed on the molybdenum film. As a result, as shown in FIGS. 3 and 5(a), the scan line 11a, the gate electrode 11aa, the auxiliary capacitor line 11b, and the relay lines 11c and 11d are formed.

While, in this embodiment, the molybdenum film having a monolayer structure is illustrated as a metal film which is included in the gate electrode 11aa, the gate electrode 11aa may include, for example, a metal film, such as an aluminum film, a tungsten film, a tantalum film, a chromium film, a titanium film, a copper film, etc., or an alloy or metal nitride film thereof which have a thickness of 50-300 nm.

The plastic substrate may be made of, for example, polyethylene terephthalate resin, polyethylene naphthalate resin, polyethersulfone resin, acrylic resin, or polyimide resin.

<Semiconductor Layer Forming Step>

Next, for example, a silicon nitride film (thickness: about 200-500 nm) is formed by CVD on the entire substrate on which the scan line 11a, the gate electrode 11aa, the auxiliary capacitor line 11b, and the relay lines 11c and 11d have been formed, thereby forming the gate insulating layer 12 covering the gate electrode llaa and the auxiliary capacitor line 11b.

Note that the gate insulating layer 12 may have a multilayer structure including two layers. In this case, in addition to the above silicon nitride film (SiNₓ), for example, a silicon oxide film (SiOₓ), a silicon oxide nitride film (SiOₓN_{y}, x>y), a silicon nitride oxide film (SiNₓO_{y}, x>y), etc. may be used.

In order to reduce or prevent the diffusion of an impurity etc. from the insulating substrate 10a, the lower gate insulating layer is preferably a silicon nitride film or a silicon nitride oxide film, and the upper gate insulating layer is preferably a silicon oxide film or a silicon oxide nitride film. For example, the lower gate insulating layer may be a silicon nitride film having a thickness of 100-200 nm which is formed using SiH₄ and NH₃ as reactive gas, and the upper gate insulating layer may be a silicon oxide film having a thickness of 50-100 nm which is formed using N₂O and SiH₄ as reactive gas.

In order to form the gate insulating layer 12 having a smaller gate leakage current and a higher density at low film formation temperature, the reactive gas containing a noble gas, such as argon etc., is preferably used to introduce the noble gas into the insulating film.

Thereafter, for example, an oxide semiconductor film (thickness: about 30-100 nm) made of indium gallium zinc oxide (IGZO) is formed by sputtering, and thereafter, photolithography, wet etching, and resist removal and cleaning are performed on the oxide semiconductor film. As a result, as shown in FIG. 5(b), the oxide semiconductor layer 13a is formed.

<Source/Drain Forming Step>

Moreover, for example, a titanium film (thickness: about 30-150 nm) and a copper film (thickness: about 50-400 nm) etc. are successively formed by sputtering on the entire substrate on which the oxide semiconductor layer 13a has been formed. Photolithography and wet etching are performed on the copper film, and dry etching and resist removal and cleaning are performed on the titanium film. As a result, as shown in FIG. 5(c), the signal line 16a (see FIG. 3), the source electrode 16aa, the drain electrode 16b, and the auxiliary capacitor main line 16c (see FIG. 3) are formed with the channel region C of the oxide semiconductor layer 13a being exposed.

In other words, in this step, the source electrode 16aa and the drain electrode 16b are formed by dry etching on the oxide semiconductor layer 13a formed in the semiconductor layer forming step, with the channel region C of the oxide semiconductor layer 13a being exposed.

While, in this embodiment, the multilayer structure of a titanium film and a copper film is illustrated as the metal film included in the source electrode 16aa and the drain electrode 16b, the source electrode 16aa and the drain electrode 16b may include, for example, a metal film, such as an aluminum film, a tungsten film, a tantalum film, a chromium film, etc., or an alloy or metal nitride film thereof.

The conductive material may be a light transmissive material, such as indium tin oxide (ITO), indium zinc oxide (IZO), indium tin oxide containing silicon oxide (ITSO), indium oxide (In₂O₃), tin oxide (SnO₂), zinc oxide (ZnO), titanium oxide (TiN), etc.

Wet etching may be performed instead of the above dry etching. If the substrate has a large area, dry etching is more preferable. Examples of etching gas include fluorine-based gases (e.g., CF₄, NF₃, SF₆, CHF₃, etc.), chlorine-based gases (e.g., Cl₂, BCl₃, SiCl₄, CCl₄, etc.), an oxygen gas, etc. An inert gas (e.g., helium, argon, etc.) may be added to these gases.

<Interlayer Insulating Film Forming Step>

Next, for example, a silicon nitride film, a silicon oxide film, a silicon nitride oxide film, etc. is formed by plasma-enhanced CVD on the entire substrate on which the source electrode 16aa and the drain electrode 16b have been formed (i.e., the TFT 5a has been formed). As a result, as shown in FIG. 5(d), the interlayer insulating film 17 having a thickness of about 400 nm is formed to cover the TFT 5a (i.e., the oxide semiconductor layer 13a, the source electrode 16aa, and the drain electrode 16b are covered).

Next, a resist mask is formed on the interlayer insulating film 17 by photolithography. As shown in FIG. 5(d), etching is performed to form the contact hole Cb. Thereafter, a thermal treatment is performed on the entire surface of the substrate.

Note that the interlayer insulating film 17 is not limited to a monolayer structure and may have a two-layer structure or a three-layer structure.

<Planarization Film Forming Step>

Next, a photosensitive organic insulating film made of photosensitive acrylic resin etc. and having a thickness of about 1.0-3.0 μm is applied by spin coating or slit coating on the entire substrate on which the interlayer insulating film 17 has been formed. As a result, as shown in FIG. 5(e), the planarization film 18 is formed on a surface of the interlayer insulating film 17.

<Opening Forming Step>

Next, exposure and development are performed on the planarization film 18. As a result, as shown in FIG. 5(f), an opening Ca which reaches a surface 17a of the interlayer insulating film 17 provided over the channel region C of the TFT 5a is formed in the planarization film 18.

In other words, the opening Ca reaching the interlayer insulating film 17 is formed at a portion of the planarization film 18 which is located over the channel region C.

Note that, in this case, as shown in FIG. 5(f), by the above exposure and development, the contact hole Cb reaching the drain electrode 16b is simultaneously formed in the interlayer insulating film 17 and the planarization film 18.

Therefore, the conventional contact hole Cb and the opening Ca can be simultaneously formed, i.e., the opening Ca can be formed without providing an additional fabricating step (i.e., without an increase in time and cost).

There is not a particular constraint on the formation of the opening Ca, and therefore, the size of the TFT 5a can be reduced.

Thus, in this embodiment, the opening Ca reaching the surface 17a of the interlayer insulating film 17 is formed at a portion of the planarization film 18 which is located over the channel region C of the oxide semiconductor layer 13a. Therefore, in the liquid crystal display device 50 including the bottom-gate TFT 5a, even if water molecules or ions (positive ions) in the liquid crystal layer 40 are attracted by the potential of the gate electrode 11aa etc., and get stuck as positive charge at an interface between the planarization film 18 and the liquid crystal layer 40 on the planarization film 18, the downward diffusion of these water molecules or ions in the planarization film 18 over the channel region C of the TFT 5a can be reduced or prevented, and the occurrence of charge (positive charge) at an interface between the interlayer insulating film 17 and the planarization film 18 can be reduced or prevented.

<Pixel Electrode Forming Step>

Finally, a transparent conductive film, such as an indium tin oxide (ITO) film (thickness: about 50-200 nm) etc., is formed by sputtering on the entire substrate on which the interlayer insulating film 17 and the planarization film 18 have been formed. Thereafter, photolithography, wet etching, and resist removal and cleaning are performed on the transparent conductive film. As a result, as shown in FIG. 4, the pixel electrode 19a, the gate terminal 19b, the source terminal 19c, and the auxiliary capacitor terminal 19d (see FIG. 3) are formed.

In this case, as shown in FIG. 4, the pixel electrode 19a is formed on surfaces of the planarization film 18 and the interlayer insulating film 17 to cover a surface of the opening Ca formed in the planarization film as well as a surface of the contact hole Cb.

In other words, in this embodiment, the pixel electrode 19a is provided on the surface of the opening Ca (i.e., the surface 17a of the interlayer insulating film 17 and the surface 18a of the planarization film 18 in the opening Ca). Therefore, the channel region C of the oxide semiconductor layer 13a is covered by the pixel electrode 19a, whereby the formation of a back channel in the channel region C of the oxide semiconductor layer 13a due to charge can be reliably reduced or prevented.

Note that when the liquid crystal display device 50 is of light transmissive type, the pixel electrode 19a may be made of indium oxide or indium zinc oxide containing tungsten oxide, indium oxide or indium tin oxide containing titanium oxide, etc. Instead of the above indium tin oxide (ITO), indium zinc oxide (IZO), indium tin oxide containing silicon oxide (ITSO), etc. may be used.

When the liquid crystal display device 50 is of reflective type, a conductive film made of titanium, tungsten, nickel, gold, platinum, silver, aluminum, magnesium, calcium, lithium, or an alloy thereof may be used as a reflective metal thin film, and the metal thin film may be used as the pixel electrode 19a.

Thus, the active matrix substrate 20a of FIG. 4 can be fabricated.

<Counter Substrate Fabricating Process>

Initially, for example, a black-colored photosensitive resin is applied on an entire insulating substrate 10b, such as a glass substrate etc., by spin coating or slit coating, and thereafter, exposure and development are performed on the applied film. As a result, as shown in FIG. 6(a), a black matrix 21 having a thickness of about 1.0 μm is formed.

Next, on the entire substrate on which the black matrix 21 has been formed, a red-, green-, or blue-colored photosensitive resin is applied by spin coating or slit coating, and thereafter, exposure and development are performed on the applied film, thereby forming a color layer 22 with a selected color (e.g., a red color layer) having a thickness of about 2.0 μm. Moreover, by repeating a similar process for the two other colors, color layers 22 with the two other colors (e.g., a green color layer and a blue color layer) each having a thickness of about 2.0 μm are formed.

Moreover, a transparent conductive film, such as an ITO film etc., is deposited by sputtering on the substrate on which the color layers 22 have been formed. As a result, as shown in FIG. 6(b), the common electrode 23 having a thickness of about 50-200 nm is formed.

Finally, a photosensitive resin is applied by spin coating or split coating on the substrate on which the common electrode 23 has been formed, and thereafter, exposure and development are performed on the applied film. As a result, as shown in FIG. 6(c), the photospacer 24 having a thickness of about 4 μm is formed.

Thus, the counter substrate 30 can be fabricated.

<Liquid Crystal Injecting Process>

Initially, a polyimide resin film is applied by a printing method on each of a surface of the active matrix substrate 20a fabricated in the active matrix substrate fabricating process and a surface of the counter substrate 30 fabricated in the counter substrate fabricating process, and thereafter, baking and rubbing are performed on the applied films, thereby forming alignment films.

Next, a frame-like sealing member made of, for example, an ultraviolet (UV) and thermal curing resin is printed on the surface of the counter substrate 30 on which the alignment film has been formed, and thereafter, a liquid crystal material is dropped into a region inside the sealing member.

Moreover, the counter substrate 30 on which the liquid crystal material has been dropped, and the active matrix substrate 20a on which the alignment film has been formed, are joined with each other under reduced pressure. Thereafter, the counter substrate 30 and the active matrix substrate 20a thus joined with each other are exposed to the atmosphere so that pressure is applied on the front and rear surfaces of the two-substrate structure.

Thereafter, the sealing member interposed between the counter substrate 30 and the active matrix substrate 20a joined with each other is irradiated with UV light and then heated, whereby the sealing member is cured.

Finally, the two-substrate structure in which the sealing member has been cured is cut by dicing to remove an unnecessary portion.

Thus, the liquid crystal display device 50 of this embodiment can be manufactured.

According to this embodiment described above, the following advantages can be obtained.

(1) In this embodiment, the opening Ca reaching the surface 17a of the interlayer insulating film 17 is formed at a portion of the planarization film 18 which is located over the channel region C of the oxide semiconductor layer 13a. Therefore, in the liquid crystal display device 50 including the bottom-gate TFT 5a, even if water molecules or ions (positive ions) in the liquid crystal layer 40 are attracted by the potential of the gate electrode 11aa etc., and get stuck as positive charge at the interface between the planarization film 18 and the liquid crystal layer 40 on the planarization film 18, the downward diffusion of these water molecules or ions in the planarization film 18 over the channel region C of the TFT 5a can be reduced or prevented, and the occurrence of charge (positive charge) at the interface between the interlayer insulating film 17 and the planarization film 18 can be effectively reduced or prevented. As a result, the formation of a back channel in the channel region C of the TFT 5a due to the charge can be reduced or prevented. Therefore, variations in threshold voltage and the occurrence of a leakage current of the TFT 5a can be reduced, whereby a degradation in TFT characteristics can be effectively reduced.

(2) Variations in threshold voltage and the occurrence of a leakage current of the TFT 5a can be reduced or prevented, whereby a degradation in characteristics of the TFT 5a can be effectively reduced or prevented. Therefore, for example, not only a TFT having a leakage current low enough to allow the TFT to be used in a pixel switching element, but also a TFT having a threshold voltage low enough to allow the TFT to be used in a peripheral circuit and which can be driven at high speed, can be provided.

(3) In this embodiment, the pixel electrode 19a is provided on the surface of the opening Ca. Therefore, the channel region C of the oxide semiconductor layer 13a is covered by the pixel electrode 19a, whereby the formation of a back channel in the channel region C of the oxide semiconductor layer 13a due to charge can be reliably reduced or prevented. As a result, variations in threshold voltage and the occurrence of a leakage current of the TFT 5a can be reliably reduced or prevented.

(4) In this embodiment, the oxide semiconductor layer 13a is used as the semiconductor layer of the TFT 5a. Therefore, compared to a TFT employing amorphous silicon in the semiconductor layer, the TFT 5a has a higher electron mobility and can be formed by a lower-temperature process.

(5) In this embodiment, the oxide semiconductor layer 13a is made of In—Ga—Zn—O metal oxide. Therefore, the thin film transistor 5a has satisfactory properties, i.e., a high mobility and a low off current.

### Second Embodiment

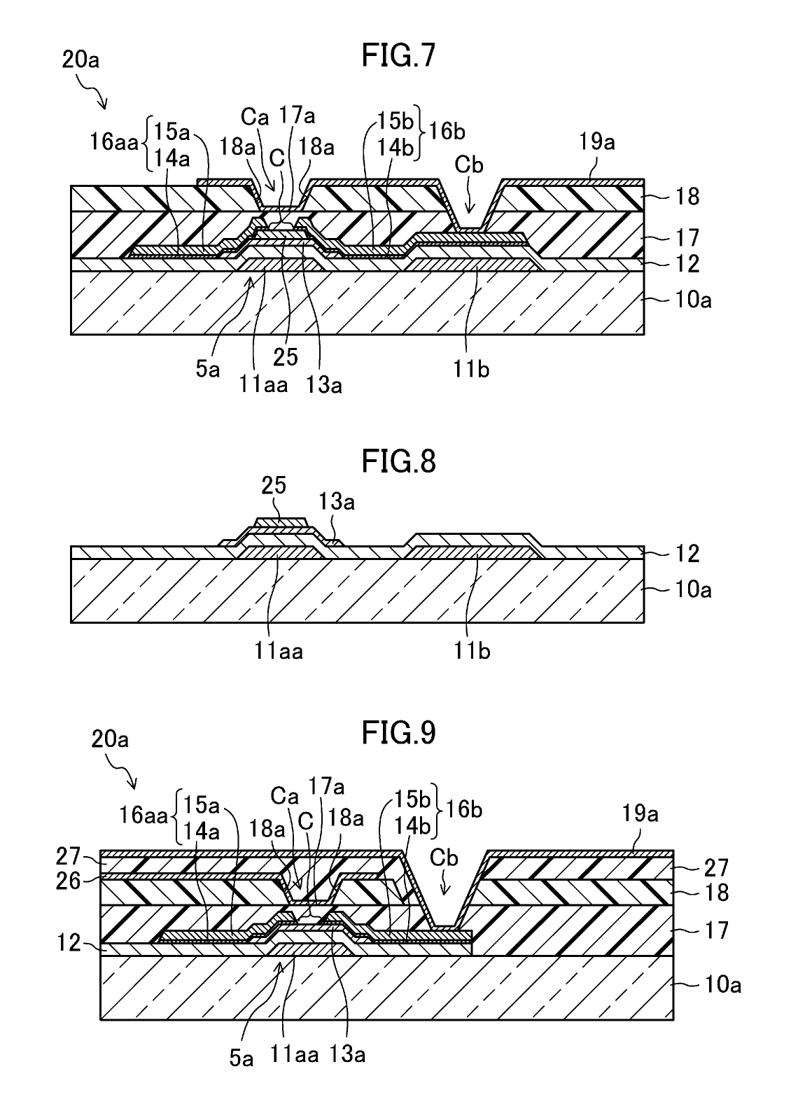

Next, a second embodiment of the present invention will be described. FIG. 7 is a cross-sectional view of an active matrix substrate including a thin film transistor according to a second embodiment of the present invention, corresponding to FIG. 4. Note that, in this embodiment, parts similar to those of the first embodiment are indicated by the same reference characters and will not be redundantly described. An entire configuration of the liquid crystal display device and a method for manufacturing the liquid crystal display device are similar to those of the first embodiment and will not be described in detail.

In this embodiment, as shown in FIG. 7, a channel protection layer (etch stop layer) 25 for protecting the channel region C is provided on the channel region C of the oxide semiconductor layer 13a.

With this configuration, when patterning is performed by etching to form the source electrode 16aa and the drain electrode 16b in the source/drain forming step, the channel region C of the oxide semiconductor layer 13a can be protected from etching.

The present invention is applicable not only to the channel-etched TFT structure described in the first embodiment, but also to the channel-protected TFT structure described in this embodiment.

Next, an example method for manufacturing the liquid crystal display device 50 of this embodiment will be described with reference to FIG. 8. FIG. 8 is a cross-sectional view for describing a process of fabricating the TFT and the active matrix substrate.

Initially, in the TFT and active matrix substrate fabricating process, similar to FIGS. 5(a) and 5(b) described in the first embodiment, a gate electrode forming step and a semiconductor layer forming step are performed.

<Channel Protection Layer Forming Step>

Next, for example, a silicon nitride film, a silicon oxide film, a silicon nitride oxide film, etc. is formed by plasma-enhanced CVD on the entire substrate on which the oxide semiconductor layer 13a has been formed. Thereafter, photolithography, etching, and resist removal and cleaning are performed using a resist as a mask. As a result, as shown in FIG. 8, the channel protection layer (etch stop layer) 25 having a thickness of about 50-100 nm for protecting the channel region C is formed on the channel region C of the oxide semiconductor layer 13a.

Next, similar to FIGS. 5(c)-5(f) described in the first embodiment, a source/drain forming step, an interlayer insulating film forming step, a planarization film forming step, an opening forming step, and a pixel electrode forming step are performed. As a result, the active matrix substrate 20a of FIG. 7 can be fabricated.

Moreover, by performing the counter substrate fabricating process and the liquid crystal injecting process described in the first embodiment, the liquid crystal display device 50 of this embodiment can be fabricated.

According to this embodiment, the following advantage can be obtained in addition to the advantages (1)-(5).

(6) In this embodiment, the channel protection layer 25 for protecting the channel region C is provided on the channel region C of the oxide semiconductor layer 13a. Therefore, when patterning is performed by etching to form the source electrode 16aa and the drain electrode 16b in the step of forming the source electrode 16aa and the drain electrode 16b, the channel region C of the oxide semiconductor layer 13a can be protected from etching.

Note that the above embodiments may be changed or modified as follows.

As shown in FIG. 9, in the active matrix substrate 20a of FIG. 4, for example, a transparent electrode 26 may be provided on a surface of the planarization film 18, another interlayer insulating film 27 may be provided on a surface of the transparent electrode 26, and the pixel electrode 19a may be provided on a surface of the other interlayer insulating film 27. With such a configuration, the transparent electrode 26 and the pixel electrode 19a can form an auxiliary capacitor, and therefore, as shown in FIG. 9, it is no longer necessary to form the auxiliary capacitor line 11b in the same layer in which the thin film transistor 5a is provided, whereby the aperture ratio of the pixel portion of the active matrix substrate can be increased. Moreover, the transparent electrode 26 provided on the surface of the planarization film 18 functions as a noise shielding electrode, whereby the voltages of the source electrode 16aa and the drain electrode 16b can be stabilized.

Note that the transparent electrode 26 may be made of a light transmissive material, such as indium tin oxide (ITO), indium zinc oxide (IZO), indium tin oxide containing silicon oxide (ITSO), indium oxide (In₂O₃), tin oxide (SnO₂), zinc oxide (ZnO), titanium oxide (TiN), etc.

While, in the above embodiments, the oxide semiconductor layer 13a is employed as the semiconductor layer, the semiconductor layer is not limited to this. Instead of the oxide semiconductor layer 13a, for example, a silicon-based semiconductor layer made of amorphous silicon or polysilicon may be used as the semiconductor layer of the TFT 5a.

While, in the above embodiments, the oxide semiconductor layer made of indium gallium zinc oxide (IGZO) is used as the oxide semiconductor layer 13a, the oxide semiconductor layer 13a is not limited to this. For example, the oxide semiconductor layer 13a may be made of a metal oxide material containing at least one of indium (In), gallium (Ga), aluminum (Al), copper (Cu), zinc (Zn), magnesium (Mg), and cadmium (Cd). The oxide semiconductor layer 13a made of the material can have a high mobility even if the oxide semiconductor layer 13a is in the amorphous state, and therefore, can provide a large on resistance of the switching element. Therefore, the difference in output voltage during data read operation increases, resulting in an improvement in the S/N ratio. The oxide semiconductor layer 13a may be an oxide semiconductor film made of, for example, InGaO₃(ZnO)₅, MgₓZn₁₋ₓO, CdₓZn₁₋ₓO, CdO, etc., in addition to IGZO (In—Ga—Zn—O).

Amorphous or polycrystalline ZnO doped with one or more impurities selected from the Group 1, 13, 14, 15, or 17 elements, or the ZnO in a microcrystalline state in which the amorphous ZnO and the polycrystalline ZnO coexist, or the ZnO without the impurities, may be employed.

### INDUSTRIAL APPLICABILITY

The present invention is useful for thin film transistor substrates including a semiconductor layer made of an oxide semiconductor, methods for manufacturing the thin film transistor substrates, and display devices.

### DESCRIPTION OF REFERENCE CHARACTERS

5a THIN FILM TRANSISTOR

10a INSULATING SUBSTRATE

11aa GATE ELECTRODE

12 GATE INSULATING LAYER

13a OXIDE SEMICONDUCTOR LAYER (SEMICONDUCTOR LAYER)

16aa SOURCE ELECTRODE

16b DRAIN ELECTRODE

17 INTERLAYER INSULATING FILM

18 PLANARIZATION FILM

19a PIXEL ELECTRODE

20a ACTIVE MATRIX SUBSTRATE (THIN FILM TRANSISTOR SUBSTRATE)

25 CHANNEL PROTECTION LAYER

30 COUNTER SUBSTRATE

40 LIQUID CRYSTAL LAYER (DISPLAY MEDIUM LAYER)

50 LIQUID CRYSTAL DISPLAY DEVICE

C CHANNEL REGION

Ca OPENING

1: A thin film transistor substrate comprising:
an insulating substrate;
a gate electrode provided on the insulating substrate;
a gate insulating layer covering the gate electrode;
a semiconductor layer provided on the gate insulating layer over the gate electrode and having a channel region;
a source electrode and a drain electrode provided on the semiconductor layer, overlapping the gate electrode and facing each other with the channel region being interposed between the source electrode and the drain electrode;
an interlayer insulating film covering the semiconductor layer, the source electrode, and the drain electrode;
a planarization film provided on the interlayer insulating film; and
a pixel electrode provided on the planarization film,
wherein
an opening reaching the interlayer insulating film is formed at a portion of the planarization film which is located over the channel region.

2: The thin film transistor substrate according to claim 1, wherein
the pixel electrode is provided on a surface of the opening.

3: The thin film transistor substrate according to claim 1, wherein
a channel protection layer is provided on the channel region of the semiconductor layer to protect the channel region.

4: The thin film transistor substrate according to claim 1, wherein
the semiconductor layer is an oxide semiconductor layer.

5: The thin film transistor substrate according to claim 4, wherein
the oxide semiconductor layer is made of metal oxide containing at least one selected from the group consisting of indium (In), gallium (Ga), aluminum (Al), copper (Cu), and zinc (Zn).

6: The thin film transistor substrate according to claim 5, wherein
the oxide semiconductor layer is made of indium gallium zinc oxide (IGZO).

7: The thin film transistor substrate according to claim 1, wherein
the semiconductor layer is a silicon-based semiconductor layer.

8: A display device comprising:
the thin film transistor substrate according to claim 1;
a counter substrate facing the thin film transistor substrate; and
a display medium layer provided between the thin film transistor substrate and the counter substrate.

9: The display device according to claim 8, wherein
the display medium layer is a liquid crystal layer.

10: A method for manufacturing a thin film transistor substrate including an insulating substrate, a gate electrode provided on the insulating substrate, a gate insulating layer covering the gate electrode, a semiconductor layer provided on the gate insulating layer over the gate electrode and having a channel region, a source electrode and a drain electrode provided on the semiconductor layer, overlapping the gate electrode and facing each other with the channel region being interposed between the source electrode and the drain electrode, an interlayer insulating film covering the semiconductor layer, the source electrode, and the drain electrode, a planarization film provided on the interlayer insulating film, and a pixel electrode provided on the planarization film, the method comprising at least:
a gate electrode forming step of forming the gate electrode on the insulating substrate;
a semiconductor layer forming step of forming the gate insulating layer covering the gate electrode formed in the gate electrode forming step, and thereafter, forming the semiconductor layer on the gate insulating layer;
a source/drain forming step of forming the source electrode and the drain electrode on the oxide semiconductor layer formed in the semiconductor layer forming step, and exposing the channel region of the oxide semiconductor layer;
an interlayer insulating film forming step of forming the interlayer insulating film covering the semiconductor layer, the source electrode, and the drain electrode;
a planarization film forming step of forming the planarization film on a surface of the interlayer insulating film; and
an opening forming step of forming an opening reaching the interlayer insulating film at a portion of the planarization film which is located over the channel region.
